(19) United States
(12) Patent Application Publication
(10) Pub. No.: US 2023/0345633 A1
(43) Pub. Date: Oct. 26, 2023

(54) PRINTED CIRCUIT BOARD WITH EMBEDDED BUMP PADS

(71) Applicant: Western Digital Technologies, Inc., San Jose, CA (US)

(72) Inventors: Kent Yang, Taichung (TW); Jackson Wang, Taichung (TW); Jack Yang, Taichung (TW); Olga Chen, Taichung (TW); Milton Tzeng, Taichung (TW); Jinxiang Huang, Shanghai (CN)

(21) Appl. No.: 17/726,990

(22) Filed: Apr. 22, 2022

(51) Int. Cl. H05K 1/11; H05K 3/40; H05K 3/24

(52) U.S. Cl. CPC H05K 1/111; H05K 3/4007; H05K 3/24; H05K 2201/10378; H05K 2201/10734

(57) ABSTRACT

A Printed Circuit Board (PCB) or substrate has a bump pad layer and a separate trace metal layer. The bump pad layer substantially covers or overlays the trace metal layer. A first surface of a bump pad in the bump pad layer is electrically coupled to a trace in the trace metal layer. A second surface of the bump pad in the bump pad layer extends above a surface of the bump pad layer. When a component is mounted on the substrate during a component mounting process, a pillar or other electrical connection mechanism of the component is electrically coupled to the bump pad without the risk of solder non-wetting and/or the formation of solder bridges between traces and bump pads on the substrate.

### BACKGROUND

Printed Circuit Boards (PCB) and substrates are used in semiconductor device packaging to fan-out signal pads of an integrated circuit or chip and electrically connect the chip with other electronic components. Chips can be connected to the substrate with bond wires in a die-up arrangement or with solder balls in a die-down or flip-chip arrangement. For a flip-chip connection, the substrate typically uses a bump-on-trace design to interconnect with a copper pillar and associated solder bump on the chip. However, existing flip-chip (FC) substrate designs suffer from various shortcomings. For example, when a chip is interconnected with a FC substrate, the chip may move or shift during placement. As a result, the solder bump may cause a solder bridge to form between a bump pad on the FC substrate and an adjacent trace on the FC substrate. In another example, traces and/or bump pads on the FC substrate may be embedded in a prepeg. In this configuration, a surface of the bump pad and/or a trace are lower than the surface of the prepreg. During placement of the chip on the FC substrate, the solder bump and copper pillar of the chip may not reach and/or bond (e.g., non-wetting) with a particular bump pad due to the difference in height between the surface of the bump pad and the surface of the prepreg.

Accordingly, it would be advantageous for a PCB or substrate to reduce and/or eliminate the risk of solder bridges between bump pads and adjacent traces during a chip mounting process. Additionally, it would be advantageous to reduce or eliminate solder non-wetting between a bump pad and a solder bump of a copper pillar of a chip during the chip mounting process.

### SUMMARY

The present application describes a Flip Chip-Chip Scale Package (FCCSP) substrate (also referred to herein as a flip chip substrate) that reduces and/or eliminates the risk of a solder bridge forming between bump pads and/or traces on the FCCSP substrate when a chip or substrate is mounted to the FCCSP substrate. The FCCSP substrate of the present disclosure also reduces or eliminates the risk of solder non-wetting between a copper pillar (or other electrical connection mechanism) of the chip and an associated bump pad on the FCCSP substrate when a chip is mounted to the FCCSP substrate.

For example, the flip chip substrate described herein includes a bump pad layer disposed on a topmost surface of the flip chip substrate. The bump pad layer is comprised of at least one bump pad embedded in an etchable dielectric material. During the flip chip substrate fabrication process, the etchable dielectric material undergoes an etching process such that a first surface (e.g., a top surface) of the bump pad extends above a top surface of the etchable dielectric material.

The flip chip substrate also includes a trace metal layer disposed underneath the bump pad layer. The trace metal layer includes at least one trace embedded in a dielectric material. The at least one trace is positioned within the dielectric material such that the at least one trace is electrically coupled to a second surface (e.g., a bottom surface) of the bump pad in the bump pad layer.

In this configuration, the bump pad is the sole interconnection point between a copper pillar (or other electrical connection mechanism) of the chip and the flip chip substrate. Thus, the design of the flip chip substrate described herein reduces and/or eliminates the issues described above.

Accordingly, the present application describes a printed circuit board that includes a bump pad layer and a trace metal layer. The bump pad layer includes a bump pad embedded in a first dielectric material. A first portion of the bump pad extends above a surface of the first dielectric material. The trace metal layer includes a trace embedded in a second dielectric material. The second dielectric material is different than the first dielectric material. The trace metal layer is coupled to the bump pad layer such that the trace is electrically coupled to a second portion of the bump pad.

The present application also describes a method for manufacturing a printed circuit board. The method includes plating a bump pad on a separable bi-metal foil. The bump pad is laminated with an etchable dielectric material to form a bump pad layer. A first side of the bump pad layer is plated with a trace such that the trace is electrically coupled to a first side of the bump pad. The trace is laminated with a dielectric material to form a trace metal layer. The separable bi-metal foil is removed from the bump pad layer to expose a second side of the bump pad layer. The second side of the bump pad layer is etched such that a portion of a second side of the bump pad extends above a surface of the etchable dielectric material.

Also described is a printed circuit board that includes a bump pad layer and a trace metal layer separate from the bump pad layer. The bump pad layer includes a first connection means embedded in an etchable dielectric material. The etchable dielectric material is etched such that a first portion of the first connection means extends above a surface of the etchable dielectric material. The trace metal layer includes a second connection means embedded in a second dielectric material. The second connection means is electrically coupled to a second portion of the first connection means. The first connection means acts to prevent solder non-wetting between the first connection means and a solder bump associated with a component during a component mounting process and acts to prevent a solder bridge from forming between adjacent first connection means on the printed circuit board during the component mounting process.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates an example of an existing design of a FCCSP substrate having non-embedded bump pads and traces in which a solder bridge has formed between a bump pad and an adjacent trace.

FIG. 2 illustrates an example of an existing design of a FCCSP substrate having embedded bump pads and traces in which solder non-wetting has occurred between a pillar of a component and one of the embedded bump pads.

FIG. 3 illustrates a first operation of a flip chip substrate manufacturing process in which bump pads are plated on a separable bi-metal foil and an associated detach core according to an example.

FIG. 4 illustrates a second operation of a flip chip substrate manufacturing process in which the bump pads of FIG. 3 are laminated with an etchable dielectric material to form a bump pad layer according to an example.

FIG. 5 illustrates a third operation of a flip chip substrate manufacturing process in which an exposed surface of the etchable dielectric material has undergone an etching process according to an example.

FIG. 6 illustrates a fourth operation of a flip chip substrate manufacturing process in which one or more traces are plated on an etchable dielectric material and in which the one or more traces are connected to the bump pad layer of FIG. 5 according to an example.

FIG. 7 illustrates a fifth operation of a flip chip substrate manufacturing process in which the one or more traces of FIG. 6 are laminated with a dielectric material to form a trace metal layer and additional metal layers, additional associated dielectric layers and a solder mask are added to the trace metal layer according to an example.

FIG. 8 illustrates a sixth operation of a flip chip substrate manufacturing process in which the detach core and a second layer of the separable bi-metal foil are removed from the flip chip substrate according to an example.

FIG. 9 illustrates a seventh operation of a flip chip substrate manufacturing process in which the first layer of the separable bi-metal foil is etched from the flip chip substrate according to an example.

FIG. 10 illustrates an eighth operation of a flip chip manufacturing process in which an exposed surface of the etchable dielectric material that comprises the bump pad layer undergoes an etching process such that at least a portion of the bump pad extends above a surface of the etchable dielectric material according to an example.

FIG. 11 illustrates a component being mounted to a flip chip substrate according to an example.

FIG. 12 illustrates a method for manufacturing a printed circuit board according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

Flip Chip-Chip Scale Package (FCCSP) substrates typically use a bump-on-trace (BOT) design to interconnect with a chip or other substrate. For example, in current FCCSP substrate designs, the FCCSP substrate includes a number of bump pads and traces. During a mounting process in which the chip (or another substrate) is mounted to the FCCSP substrate, the chip is turned over and a copper pillar and solder bump (or other electrical connection component(s)) on the chip is interconnected with a bump pad on the FCCSP substrate. However, during placement of the chip on the FCCSP substrate, a solder bridge may form between the bump pad on the FCCSP substrate and an adjacent trace on the FCCSP substrate. This may be caused by movement of the chip during placement and/or spacing considerations between the bump pad and adjacent traces.

In another example, the traces and bump pads of the FCCSP substrate may be embedded in a prepeg. In this configuration, surfaces of the bump pads and traces are lower than the surface of the prepreg. During placement of the chip on the FCCSP substrate, a solder bump on a copper pillar of the chip may not reach and/or bond with a bump pad in a particular well formed by the prepeg.

In order to address the above, the present application describes a flip chip substrate in which the bump pads are provided in a topmost bump pad layer and the traces are provided a in a separate trace metal layer that is below the bump pad layer. The bump pads in the bump pad layer are embedded in an etchable dielectric material. During a flip chip substrate fabrication process, the etchable dielectric material undergoes an etching process that exposes at least a top portion of the bump pad.

When a component (e.g., a chip, a substrate) is mounted to the flip chip substrate during a component mounting process, a copper pillar (or other electrical connection mechanism) on the component is interconnected with the exposed surface of the bump pad.

The trace metal layer includes a trace embedded in a dielectric material. The trace is positioned within the dielectric material such that the trace is electrically coupled to a second surface (e.g., a bottom surface) of the bump pad in the bump pad layer.

As will be explained herein, the bump pad in the bump pad layer may be the sole electrical interconnection point between the chip and the flip chip substrate. As such, the flip chip substrate described herein reduces or eliminates the risk of solder bridges forming between a bump pad and an adjacent trace during a component mounting process and also reduces or eliminates the risk of solder non-wetting between the bump pad and a solder bump associated with the component during the component mounting process.

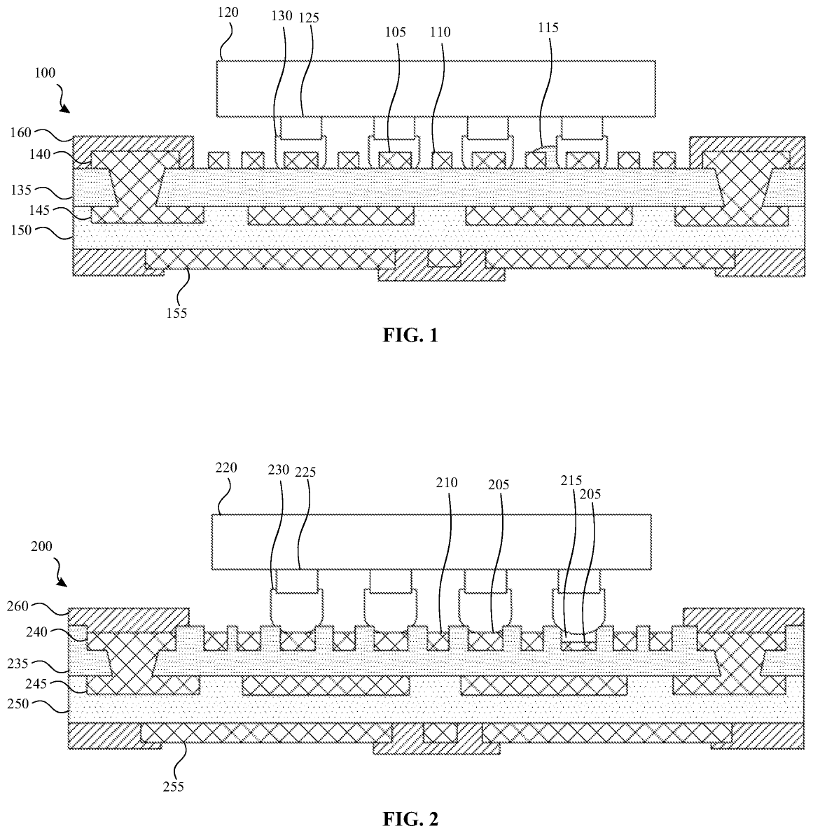

These and other examples will be shown and described with respect to FIG. 1-FIG. 12.

FIG. 1 illustrates an example of an existing design of an FCCSP substrate 100 having non-embedded bump pads 105 and traces 110. In the example shown in FIG. 1, the FCCSP substrate 100 includes three metal layers separated by dielectric layers. For example, the FCCSP substrate 100 includes a first metal layer 140, a prepeg layer 135, a second metal layer 145, a dielectric layer 150 and a third metal layer 155. The FCCSP substrate 100 may also include a solder mask 160.

One of the limitations of the FCCSP substrate 100 is that when a chip 120 is mounted to the FCCSP substrate 100, a solder bridge 115 may form between a bump pad 105 and an adjacent trace 110 of the FCCSP substrate 100. For example, the chip 120 includes a copper pillar 125 (or other electrical connection mechanism) having a solder bump 130. The copper pillar 125 is configured to interconnect with the bump pad 105. However, if the chip 120 moves during a mounting process, the risk of the solder bridge 115 forming increases. The risk is further increased as spacing between bump pads 105 and traces 110 gets smaller. The risk of a solder bridge 115 forming also increases as a bump pitch (e.g., the spacing between copper pillars 125) decreases.

FIG. 2 illustrates another example of an existing design of an FCCSP substrate 200 having embedded bump pads 205 and traces 210. In the example shown in FIG. 2, the FCCSP substrate 200 include three metal layers separated by dielectric layers. For example, the FCCSP substrate 200 includes a first metal layer 240, a prepeg layer 235 in which the bump pads 205 and traces 210 are embedded, a second metal layer 245, a dielectric layer 250 and a third metal layer 255. The FCCSP substrate 200 may also include a solder mask 260.

One of the limitations of the FCCSP substrate 200 is that when a chip 220 is mounted to the FCCSP substrate 200, solder non-wetting 215 may occur between a copper pillar 225 (or other electrical connection mechanism, such as a solder bump 230) of the chip 220 and one of the embedded bump pads 205. For example and as shown in FIG. 2, a depth of one embedded bump pad 205 may be deeper within a well formed by the prepeg when compared to another bump pad 205. Other factors that may contribute to solder non-wetting include movement of the chip 220 during a chip mounting process. The risk of solder non-wetting also increases as spacing between bump pads 205 and traces 210 gets smaller and/or as a bump pitch (e.g., the spacing between copper pillars 225 on the chip 220) decreases.

As previously described and in order to address the above, the flip chip substrate described herein includes an outermost and/or topmost bump pad layer having at least one bump pad that protrudes from the top surface of the bump pad layer. When a component (e.g., a chip, a substrate) is mounted to the flip chip substrate during a component mounting process, a copper pillar or other connection mechanism on the component is interconnected with the exposed surface of the bump pad thereby reducing or eliminating the risks outlined above.

The flip chip substrate of the present disclosure also includes a trace metal layer disposed underneath the bump pad layer. The trace metal layer includes a trace embedded in a dielectric material. The trace is positioned within the dielectric material such that the trace is electrically coupled to a second surface (e.g., a bottom surface) of the bump pad in the bump pad layer.

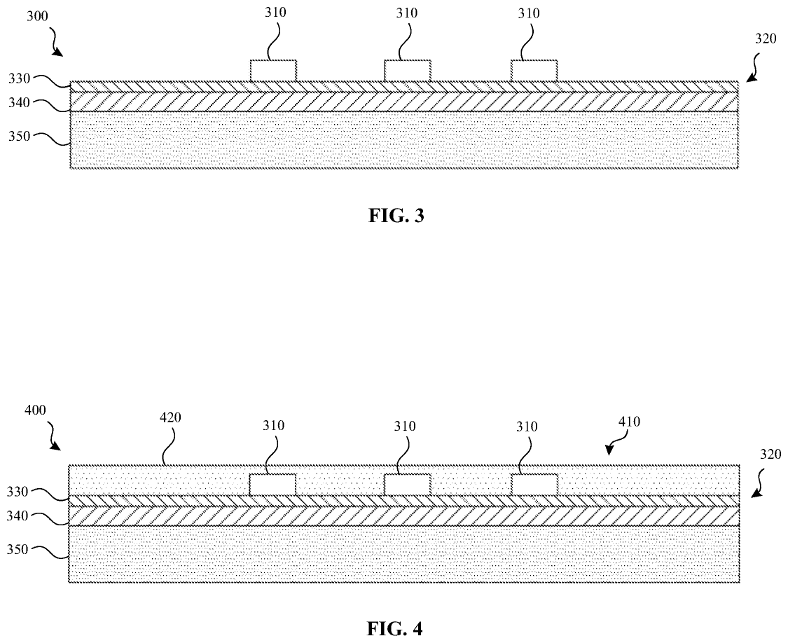

FIG. 3-FIG. 10 illustrate various operations of a printed circuit board fabrication process for fabricating the flip chip substrate of the present disclosure. Each operation will be described below with reference to the figures. In FIG. 4-FIG. 10, various reference numbers are included from earlier figures for purposes of clarity.

FIG. 3 illustrates a first operation 300 of a flip chip substrate manufacturing process according to an example. In the first operation 300, one or more bump pads 310 are plated on a separable bi-metal foil 320 and an associated detach core 350. As shown in FIG. 3, the separable bi-metal foil 320 comprises a first layer 330 and a second layer 340.

In an example, the first layer 330 is a copper seed layer. Although copper is specifically mentioned, the first layer 330 may be made of any suitable material that enables the bump pads 310 to be plated on the first layer 330. In some examples, the first layer 330 is approximately three micrometers thick although other thicknesses may be used.

The second layer 340 may also be made of copper and have a thickness of approximately eighteen micrometers. Although specific materials and dimensions are given for the second layer 340, the second layer 340 may be made of any suitable material and have any suitable thickness.

In some examples, the bump pads 310 may be formed using any suitable plating technique. The bump pads 310 may be made from various metal materials (or other electrically conductive materials). Example metal materials include, but are not limited to, copper, aluminum, gold, platinum, tungsten, molybdenum, or combinations thereof.

FIG. 4 illustrates a second operation 400 of a flip chip substrate manufacturing process according to an example. In the second operation 400, the bump pads 310 are laminated with or are otherwise embedded in an etchable dielectric material 420 thereby forming a bump pad layer 410. In one example, the etchable dielectric material 420 may be a solder mask. In another example, the etchable dielectric material 420 may be any etchable dielectric material that does not include glass fiber. For example, the etchable dielectric material 420 may be Ajinomoto Buildup Film (ABF) although materials/dielectrics may be used.

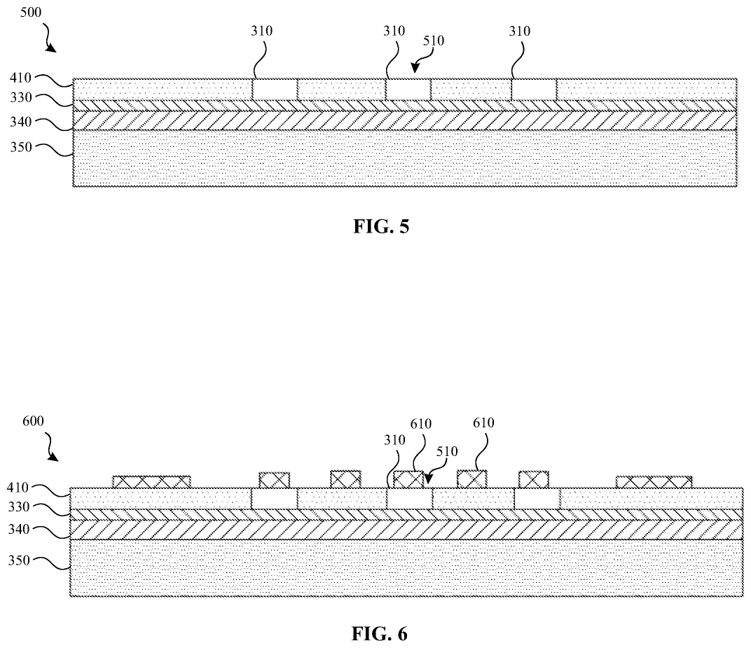

FIG. 5 illustrates a third operation 500 of a flip chip substrate manufacturing process according to an example. In the third operation 500, an exposed surface (e.g., the top surface) of the etchable dielectric material 420 (FIG. 4) of the bump pad layer 410 undergoes an etching process. In an example, this etching process is a chemical etching process although other etching processes and/or other dielectric removal processes may be used.

The etching process exposes a first surface 510 or portion of a bump pad 310 in the bump pad layer 410. When the first surface 510 of the bump pad is exposed, a fourth operation 600 (FIG. 6) of the flip chip manufacturing process may commence.

For example and referring to FIG. 6, the fourth operation 600 is one in which one or more traces 610 are plated on the bump pads 310 and/or on the etchable dielectric material 420 that comprise bump pad layer 410. The traces 610 may be made from various metal materials (or other electrically conductive materials). Examples include, but are not limited to, copper, aluminum, gold, platinum, tungsten, molybdenum, or combinations thereof.

In an example, the traces 610 may be plated on the bump pads 310 and/or on the etchable dielectric material 420 of the bump pad layer 410 using any suitable plating technique. As shown in FIG. 6, some of the traces 610 are electrically coupled to exposed first surfaces 510 of the bump pads 310 in the bump pad layer 410 while other traces are plated on the etchable dielectric material 420 of the bump pad layer 410.

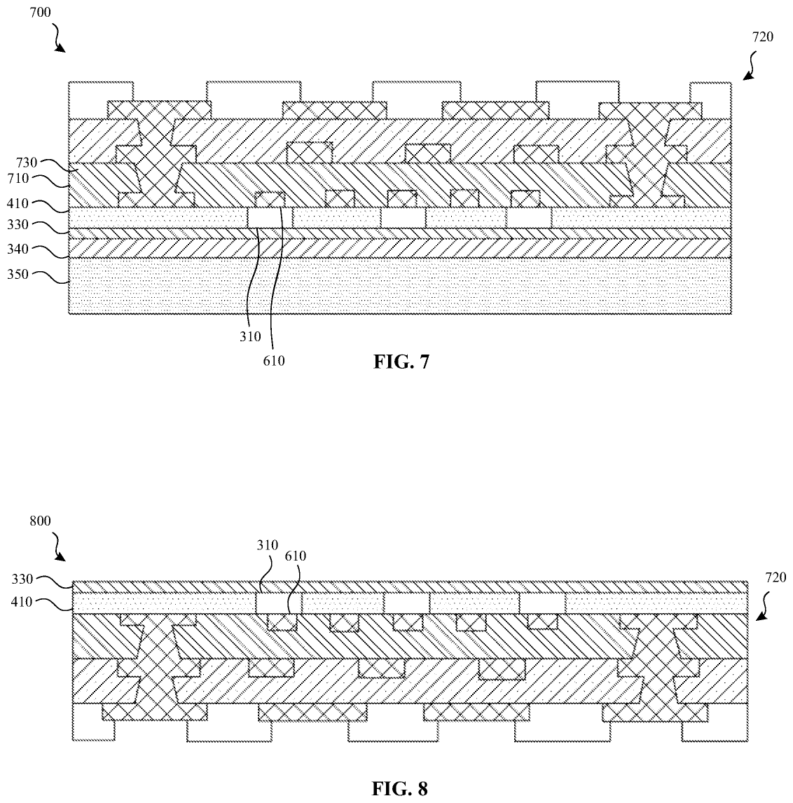

FIG. 7 illustrates a fifth operation 700 of a flip chip substrate manufacturing process according to an example. In the fifth operation 700, one or more of the traces 610 are laminated with a dielectric material 730 to form a trace metal layer 710. As shown in FIG. 7, the trace metal layer 710 may extend substantially across the bump pad layer 410. For example, the bump pad layer 410 may entirely cover, substantially cover, or partially cover the traces 610 and/or the trace metal layer 710. As such, the bump pad layer 410 reduces or eliminates any risk of a solder bridge forming between the traces 610 and/or the traces 610 and the bump pads 310.

In an example, the lamination process may be any suitable lamination process (e.g., PP12 lamination process) that embeds the traces 610 in a dielectric material 730. As shown in FIG. 7, additional metal layers, additional associated dielectric layers, and/or solder masks (represented by reference number 720) are added to the trace metal layer 710. The additional metal layers, the additional dielectric layers, and/or the solder mask(s) may be added to the trace metal layer 710 using any suitable lamination/fabrication processes (e.g., PP12 to SM processes).

Although two additional metal layers are shown, the flip chip substrate of the present disclosure may include any number of metal layers. In some examples, the metal layers may be made from various metal materials (or other electrically conductive materials). Examples include, but are not limited to, copper, aluminum, gold, platinum, tungsten, molybdenum, or combinations thereof. Likewise, the dielectric layers may be made from any suitable dielectric material(s).

FIG. 8 illustrates a sixth operation 800 of a flip chip substrate manufacturing process according to an example. As shown in FIG. 8, the sixth operation 800 is one in which the detach core 350 and the second layer 340 of the separable bi-metal foil 320 are removed from the flip chip substrate. In an example, the detach core 350 and/or the second layer 340 of the separable bi-metal foil 320, may be separated or otherwise removed from the flip chip substrate using a manual or an automated process. In the example shown in FIG. 8, the flip chip substate has been turned over such that the first layer 330 is now considered and referred to herein as the topmost layer. As shown, the first layer 330 of the bi-metal foil 320 overlays the bump pad layer 410.

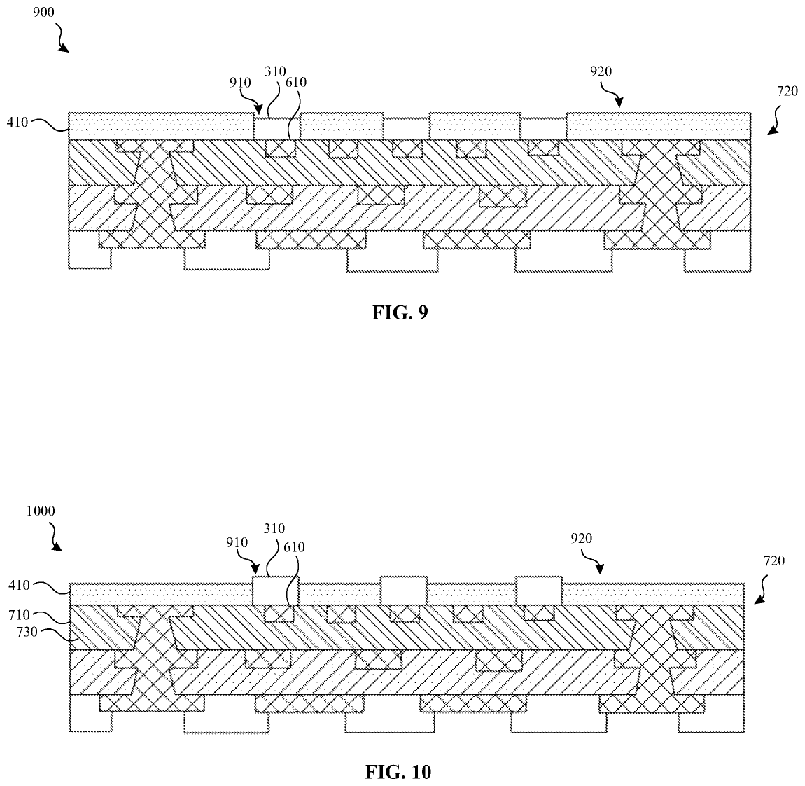

FIG. 9 illustrates a seventh operation 900 of a flip chip substrate manufacturing process according to an example. In the seventh operation 900, the first layer 330 of the bi-metal foil 320 depicted in FIG. 8 has been removed from the flip chip substrate. In an example, the first layer 330 of the bi-metal foil 320 is removed from the flip chip substrate using an etching process. In an example, the etching process is a chemical etching process.

However, in some cases, the chemical etching process may not be uniform across the entire surface of the flip chip substrate. In order to ensure that the first layer 330 is completely removed from the flip chip substrate, the flip chip substrate may be over-etched. While the over-etching process may be used to ensure the first layer 330 of the bi-metal foil 320 has been completely removed from the flip chip substrate, the over-etching process may also cause a second surface 910 of the bump pad 310 to be lower than the top surface 920 of the bump pad layer 410 such as shown in FIG. 9.

As also shown in FIG. 9, once the first layer 330 of the bi-metal foil 320 has been removed (e.g., etched) from the bump pad layer 410, the bump pad layer 410 is exposed and becomes the topmost layer of the flip chip substrate. As such, a second surface 910 or portion of the bump pad 310 is exposed. In an example, the second surface 910 of the bump pad 310 is opposite from the first surface 510 (FIG. 5) of the bump pad 310. As also shown in FIG. 9, the second surface 910 of the bump pad 310 may be below the top surface 920 of the bump pad layer 410 due to the etching process that removed the first layer 330 of the bi-metal foil 320.

FIG. 10 illustrates an eighth operation 1000 of a flip chip manufacturing process according to an example. In the eighth operation 1000, the exposed surface (e.g., the top surface 920) of the bump pad layer 410 undergoes an etching process. In an example, the etching process may be similar to the etching process that was performed in the third operation 500 (FIG. 5). For example, the etching process may be a chemical etching process or other such process that removes unwanted/unneeded dielectric material from the bump pad layer 410. As a result, the second surface 910 of the bump pad 310 extends above the top surface 920 of the bump pad layer 410.

In some examples, the second surface 910 of the bump pad 310 extends approximately ten micrometers or less (e.g., anywhere in a range between zero micrometers and ten micrometers) above the top surface 920 of the bump pad layer 410. In other examples, the second surface 910 of the bump pad 310 may extend more than ten micrometers (e.g., 15 micrometers or less, twenty micrometers or less) above the top surface 920 of the bump pad layer 410. As such, the bump pad 310 may be used as the sole connection point between the flip chip substrate and an electrical connection mechanism of a chip or substrate.

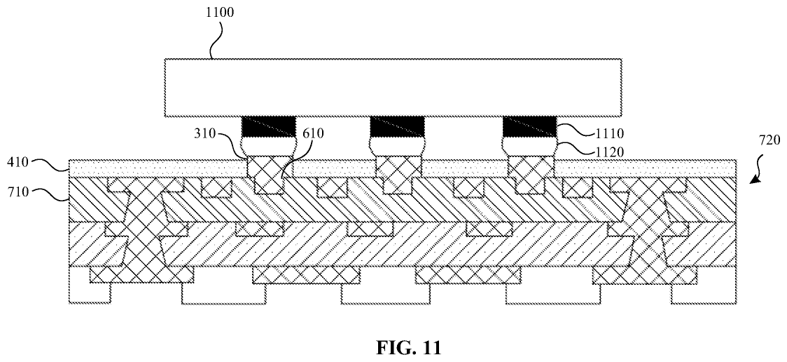

FIG. 11 illustrates a component 1100 being mounted to a flip chip substrate according to an example. The flip chip substrate shown in FIG. 11 may be the flip chip substrate that was formed using the operations outlined in FIG. 3-FIG. 10.

In an example, the component 1100 is a chip or other substrate. The component 1100 is mounted to the flip chip substrate during a component mounting process. The component includes a pillar 1110 and a solder bump 1120 or solder joint. The pillar 1110 may be made from various metal materials (or other electrically conductive materials). Example metal materials include, but are not limited to, copper, aluminum, gold, platinum, tungsten, molybdenum, or combinations thereof.

As shown in FIG. 11, the pillar 1110 and the solder bump 1120 are electrically coupled to the second surface of the bump pad 310. Because the second surface of the bump pad 310 extends above the surface of the bump pad layer 410, any risk of solder non-wetting between the pillar 1110 (or other connection mechanism) of the component and the bump pad 310 (such as shown in FIG. 2) is reduced or substantially eliminated. Additionally, because the bump pad layer 410 substantially covers the trace metal layer 710, and because the bump pad 310 is electrically coupled to the trace 610, any risk of a solder bridge forming between a bump pad 310 and a trace (such as shown in FIG. 1) is reduced or substantially eliminated.

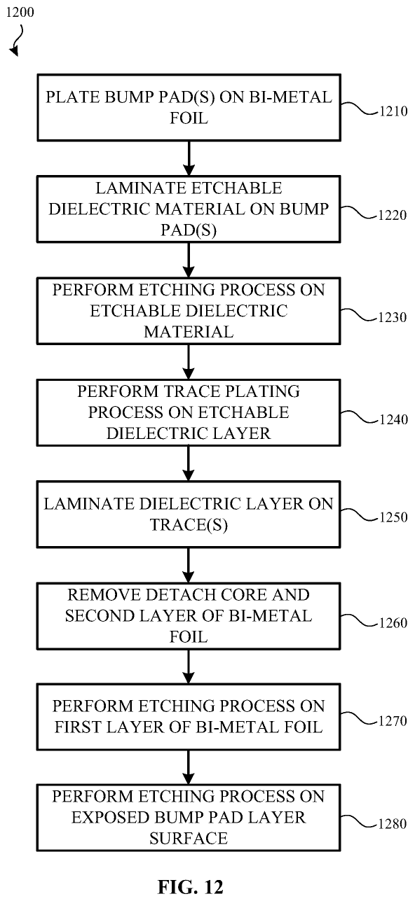

FIG. 12 illustrates a method 1200 for manufacturing a printed circuit board according to an example. The method 1200 may be used to fabricate a printed circuit board such as, for example, the flip chip substrate shown in FIG. 10.

Method 1200 begins when one or more bump pads are plated (1210) or otherwise formed on a separable bi-metal foil. The separable bi-metal foil may include a first copper layer and a second copper layer. Although first and second copper layers are specifically mentioned, each layer of the separable bi-metal foil may be comprised of other materials. In some examples, the separable bi-metal layer is associated with a detach core.

When the bump pads have been plated on the bi-metal foil, the bump pads are laminated (1220) with an etchable dielectric material. Laminating the bump pads with the etchable dielectric material forms an etchable bump pad layer. In an example, the etchable dielectric material may be any dielectric material that does not contain glass fibers.

When the etchable dielectric material has been laminated on the bump pads, the etchable dielectric material undergoes an etching process (1230). The etching process removes excess dielectric material/laminate and exposes a first surface of a bump pad. For example, the etching process may cause the first surface of the bump pad to be exposed and/or flush or substantially flush with a surface of the laminate.

A metal or trace plating process (1240) may then be performed on the etchable dielectric material. In this process, one or more metal (e.g., copper) traces are plated on the first surface of the bump pad and/or on the top/outer surface of the etchable dielectric material. In an example, this process may electrically couple a trace with an associated bump pad.

Once the trace plating process has occurred, the traces are laminated (1250) or are otherwise embedded in a dielectric material. In an example, laminating the traces with a dielectric material may form a trace metal layer. In an example, the trace metal layer is configured such that the bump pad layer entirely covers or substantially covers the traces and/or the trace metal layer. In an example, operations 1240 and 1250 (or operations similar to those described) may be repeated any number of times to add additional copper layers to the printed circuit board. Once these operations have been completed the desired number of times, a solder resist layer may be provided on various portions of the printed circuit board.

The detach core and the second layer of the bi-metal foil are removed (1260) from the printed circuit board. In an example, the removal of the detach core and/or the second layer of the bi-metal foil may be done manually. In another example, the removal of the detach core and/or the second layer of the bi-metal foil may be automated or otherwise performed by a machine, a robot, or other automated process.

Removal of the detach core and the second layer of the bi-metal foil exposes the first layer of the bi-metal foil. As such, the first layer of the bi-metal foil undergoes an etching process (1270). In some examples, the first layer of the bi-metal foil is over-etched to ensure that the first layer of the bi-metal foil has been completely removed from the printed circuit board. In an example, over-etching of the first layer of the bi-metal foil also causes a second surface of some (or all) of the bump pads to be lower than the top/outer surface of the etchable dialectic material in which the bump pads are embedded.

Accordingly, the etchable dielectric material undergoes another etching process (1280) to help ensure that the bump pads are equal to, substantially equal to, or higher than the surface of the etchable dielectric material. For example, the bump pads may protrude or otherwise extend past the surface of the etchable dielectric material by ten micrometers or less (e.g., anywhere in a range of zero micrometers to ten micrometers). As such, the bump pads may serve as easily accessible interconnection points between the printed circuit board and a chip or substrate that will be mounted to the printed circuit board.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure. While the technology described above is in terms of a FCCSP substrate, it will be apparent to those of skill in the art that the technology described is equally applicable to printed circuit boards and substrates that receive FC dies, and not just FCCSP substrates.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, and apparatuses, systems according to embodiments of the disclosure. It is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A printed circuit board, comprising:
a bump pad layer comprising a bump pad embedded in a first dielectric material, a first portion of the bump pad extending above a surface of the first dielectric material; and
a trace metal layer comprising a trace embedded in a second dielectric material, the trace metal layer coupled to the bump pad layer such that the trace is electrically coupled to a second portion of the bump pad.

2. The printed circuit board of claim 1, wherein the first portion of the bump pad is adapted to electrically couple to a pillar of a component during a component mounting process.

3. The printed circuit board of claim 1, wherein the bump pad layer prevents a solder bridge from forming between the trace in the trace metal layer and an adjacent trace in the trace metal layer during a component mounting process.

4. The printed circuit board of claim 1, wherein the bump pad layer prevents solder non-wetting between the trace in the trace metal layer and a solder bump associated with a pillar of a component during a component mounting process.

5. The printed circuit board of claim 1, wherein the bump pad extends approximately ten micrometers above the surface of the first dielectric material.

6. The printed circuit board of claim 1, wherein the bump pad layer substantially covers the trace metal layer.

7. The printed circuit board of claim 1, wherein the trace is plated on the bump pad layer.

8. A method for manufacturing a printed circuit board, comprising:
plating a bump pad on a separable bi-metal foil;
laminating the bump pad with an etchable dielectric material to form a bump pad layer;
plating a first side of the bump pad layer with a trace such that the trace is electrically coupled to a first side of the bump pad;
laminating the trace with a dielectric material to form a trace metal layer;
removing the separable bi-metal foil from the bump pad layer to expose a second side of the bump pad layer; and
etching the second side of the bump pad layer such that a portion of a second side of the bump pad extends above a surface of the etchable dielectric material.

9. The method of claim 8, further comprising etching the first side of the bump pad layer to expose the first side of the bump pad prior to plating the first side of the bump pad layer with the trace.

10. The method of claim 8, wherein the second side of the bump pad layer is adapted to electrically couple to a pillar of a component during a component mounting process.

11. The method of claim 8, further comprising plating an additional metal layer and an additional dialectic layer associated with the additional metal layer to the trace metal layer.

12. The method of claim 8, wherein the trace metal layer extends substantially across the bump pad layer.

13. The method of claim 8, wherein the bump pad layer acts to prevent a solder bridge from forming between the trace in the trace metal layer and an adjacent trace in the trace metal layer during a component mounting process in which a component is electrically coupled to the printed circuit board.

14. The method of claim 8, wherein the bump pad layer acts to prevent solder non-wetting between the trace in the trace metal layer and a solder bump associated with a pillar of a component during a component mounting process in which a component is electrically coupled to the printed circuit board.

15. The method of claim 8, wherein the second side of the bump pad extends approximately ten micrometers above the surface of the etchable dielectric material.

16. A printed circuit board, comprising:
a bump pad layer comprising a first connection means embedded in an etchable dielectric material, the etchable dielectric material being etched such that a first portion of the first connection means extends above a surface of the etchable dielectric material; and
a trace metal layer comprising a second connection means embedded in a second dielectric material, the second connection means electrically coupled to a second portion of the first connection means, wherein the first connection means:
prevents solder non-wetting between the first connection means and a solder bump associated with a component during a component mounting process; and
prevents a solder bridge from forming between adjacent first connection means on the printed circuit board during the component mounting process.

17. The printed circuit board of claim 16, wherein the first portion of the first connection means extends approximately ten micrometers or less above the surface of the etchable dielectric material.

18. The printed circuit board of claim 16, wherein the second connection means is plated on the bump pad layer.

19. The printed circuit board of claim 16, wherein the bump pad layer substantially covers the trace metal layer.

20. The printed circuit board of claim 16, wherein the etchable dielectric material is etched using a chemical etching process to connect the first and second connection means.
